(19) United States
(12) Patent Application Publication
(10) Pub. No.: US 2023/0141244 A1
(43) Pub. Date: May 11, 2023

(54) SEMICONDUCTOR STRUCTURE

(71) Applicant: ENKRIS SEMICONDUCTOR, INC., Suzhou, Jiangsu (CN)

(72) Inventor: Kai Cheng, Suzhou, Jiangsu (CN)

(73) Assignee: ENKRIS SEMICONDUCTOR, INC., Suzhou, Jiangsu (CN)

(21) Appl. No.: 17/912,822

(22) PCT Filed: Nov. 2, 2020
(86) PCT No.: PCT/CN2020/125900

§ 371 Date: Sep. 19, 2022

(30) Foreign Application Priority Data
Mar. 30, 2020 (CN) 202020438296.6

(51) Int. Cl. H01L 27/15; H01L 33/06; H01L 33/32; H01L 29/20; H01L 29/205; H01L 29/778

(52) U.S. Cl. CPC H01L 27/15; H01L 29/205; H01L 29/2003; H01L 29/7786; H01L 33/06; H01L 33/32

(57) ABSTRACT

The present disclosure provides a semiconductor structure, including: a substrate and a heterojunction structure disposed on the substrate, where the heterojunction structure includes a source region, a drain region, and a gate region disposed between the source region and the drain region, and the drain region is provided with a quantum well structure. The quantum well structure is provided in the drain region of the heterojunction structure, and the quantum well structure is used to generate photons by recombination luminescence, the photons can be radiated not only on the surface region of the potential barrier layer but also into the interior of the heterojunction structure, thereby the release process of electrons captured by the defects can be accelerated to reduce the current collapse effect as well as the dynamic on-resistance.

### TECHNICAL FIELD

The present disclosure relates to the field of semiconductor technologies, and in particular to a semiconductor structure.

### BACKGROUND

A Group III nitride semiconductor is the third generation of new semiconductor material after the first and second generation of semiconductor materials such as Si, GaAs, etc. The Group III nitride semiconductor have high saturation electron mobility, high breakdown voltage and wide forbidden band width. Because of these characteristics, a high electron mobility transistor (HEMT) device based on GaN have broad application prospects.

The existing group III nitride semiconductor HEMT devices have the phenomenon of “current collapse” when used as high-frequency devices or high-voltage high-power switching devices. That is, when the device is operated in direct current pulse mode or high frequency mode, the drain output current cannot keep up with the change of the gate control signal, and there will be a transient decrease in drain current and an increase in dynamic on-resistance, which seriously affects the application of the device. This phenomenon is ultimately caused by a polarization effect that not only brings a two-dimensional electron gas (2DEG) in the heterojunction interface channel, but also causes the formation of positively charged ionized donor with charge density substantially equal to the concentration of 2DEG on the upper surface of the potential barrier layer in the heterojunction. The principle is that when the HEMT device works in the cutoff state, the electric field strength of a side of the gate electrode biased toward the drain electrode reaches the maximum, and the electrons on the gate leap to the surface of the potential barrier layer under the action of the electric field force and migrate laterally between its surface donor energy levels toward the drain electrode, which neutralizes the ionized donors on the surface and depletes the electrons in the channel, to form a “virtual gate”. When the operating state of the HEMT device changes from cutoff to on, the electrons on the surface of the potential barrier layer migrating from the gate electrode will migrate back to the gate electrode at a slow rate. However, when the HEMT device is switched at a certain frequency, the electrons on the surface of the potential barrier layer cannot migrate back to the gate electrode in time, causing an increase in the on-state resistance, which may be several times higher than the static on-state resistance, i.e., current collapse.

In view of this, it is necessary to provide a new semiconductor structure to solve the above problem.

### SUMMARY

An object of the present disclosure is to provide a semiconductor structure to solve the problem of current collapse.

To this end, the present disclosure provides a semiconductor structure including: a substrate and a heterojunction structure disposed on the substrate, where the heterojunction structure comprises a source region, a drain region, and a gate region disposed between the source region and the drain region, and the drain region is provided with a quantum well structure.

Optionally, the quantum well structure includes an N-type semiconductor layer, a first P-type semiconductor layer, and a quantum well layer disposed between the N-type semiconductor layer and the first P-type semiconductor layer.

Optionally, the first P-type semiconductor layer includes a hole passivation layer away from the quantum well layer.

Optionally, the heterojunction structure includes, from bottom to top, a channel layer and a potential barrier layer.

Optionally, the potential barrier layer acts as an N-type semiconductor layer in the quantum well structure.

Optionally, a material combination of the channel layer and the potential barrier layer includes: GaN and AlN, GaN and InN, GaN and InAlGaN, GaAs and AlGaAs, GaN and InAlN, or InN and InAlN.

Optionally, the gate region is provided with at least one of a dielectric layer or a second P-type semiconductor layer.

Optionally, the quantum well layer is a single quantum well layer or a multiple quantum well layer.

Optionally, a material of the first P-type semiconductor layer includes at least one of GaN, AlGaN, InGaN, or AlInGaN.

Optionally, the source region is provided with a source electrode, the quantum well structure is provided with a first drain electrode, and the gate region is provided with a gate electrode; the source electrode is in ohmic contact with the heterojunction structure, and the first drain electrode is in ohmic contact with the quantum well structure, and the gate electrode is in Schottky contact with the heterojunction structure.

Optionally, the drain region is further provided with a second drain electrode, and the second drain electrode is in ohmic contact with the heterojunction structure.

Optionally, the first drain electrode and the quantum well structure are electrically insulated from the second drain electrode by an insulating layer.

Optionally, the first drain electrode is disposed between the gate electrode and the second drain electrode.

Optionally, the second drain electrode is disposed between the gate electrode and the first drain electrode.

Compared to the related art, the present disclosure has the beneficial effect of the following aspects.

1) The quantum well structure is provided in the drain region of the heterojunction structure, and the quantum well structure is used to generate photons by recombination luminescence, the photons can be radiated not only on the surface region of the potential barrier layer but also into the interior of the heterojunction structure, thereby the release process of electrons captured by the defects can be accelerated to reduce the current collapse effect as well as the dynamic on-resistance.

2) In optional embodiments, a) the quantum well structure includes an N-type semiconductor layer, a first P-type semiconductor layer, and a quantum well layer between the N-type semiconductor layer and the first P-type semiconductor layer; or b) the potential barrier layer in the heterojunction structure acts as the N-type semiconductor layer in the quantum well structure. Relative to the embodiments a) and b), the semiconductor structure can be simplified.

3) In optional embodiments, the first P-type semiconductor layer includes a hole passivation layer away from the quantum well layer. The hole passivation layer prevents electrons in the gate electrode from migrating to the first P-type semiconductor layer and from recombining with holes in the first P-type semiconductor layer. In other words, the hole passivation layer can create a high resistance blocking state between the gate electrode and the drain electrode. The hole passivation layer can be achieved by injecting H ions into the first P-type semiconductor layer. The H ions can passivate the P-type doping ion Mg of the first P-type semiconductor layer so that Mg does not generate holes.

### BRIEF DESCRIPTION OF THE DRAWINGS

FIG. 1 is a cross-sectional view illustrating a semiconductor structure according to a first embodiment of the present disclosure.

FIG. 2 is a cross-sectional view illustrating a semiconductor structure according to a second embodiment of the present disclosure.

FIG. 3 is a cross-sectional view illustrating a semiconductor structure according to a third embodiment of the present disclosure.

FIG. 4 is a cross-sectional view illustrating a semiconductor structure according to a fourth embodiment of the present disclosure.

FIG. 5 is a cross-sectional view illustrating a semiconductor structure according to a fifth embodiment of the present disclosure.

FIG. 6 is a cross-sectional view illustrating a semiconductor structure according to a sixth embodiment of the present disclosure.

FIG. 7 is a cross-sectional view illustrating a semiconductor structure according to a seventh embodiment of the present disclosure.

List of reference numerals: semiconductor structure 1, 2, 3, 4, 5, 6 and 7; substrate 10; heterojunction structure 11; source region 12a; drain region 12b; gate region 12c; channel layer 11a; potential barrier layer 11b; quantum well structure 13; N-type semiconductor layer 13a; first P-type semiconductor layer 13b; quantum well layer 13c; hole passivation layer 130; dielectric layer 14; second P-type semiconductor layer 15; source electrode 16a; first drain electrode 16b; gate electrode 16c; second drain electrode 16d; insulating layer 17.

### DETAILED DESCRIPTION OF THE EMBODIMENTS

In order to make the above-mentioned objects, features and advantages of the present disclosure more obvious and understandable, the specific embodiments of the present disclosure are described in detail below in conjunction with the accompanying drawings.

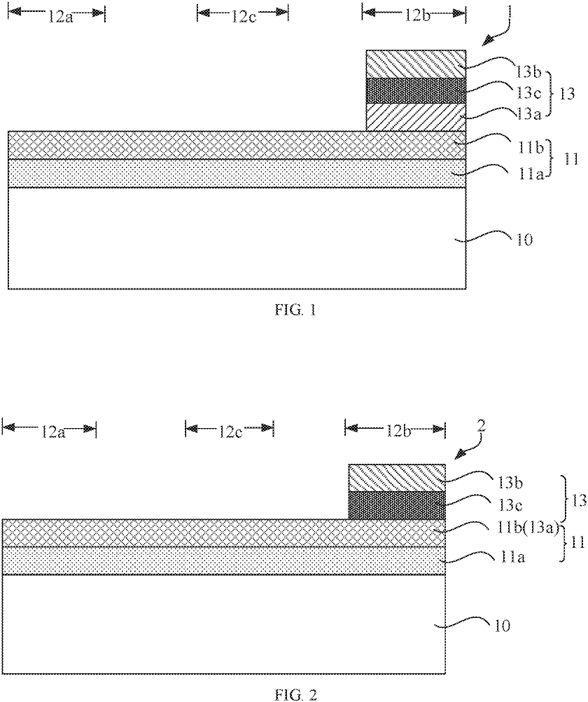

FIG. 1 is a cross-sectional view illustrating a semiconductor structure according to a first embodiment of the present disclosure.

Referring to FIG. 1, the semiconductor structure 1 includes: a substrate 10 and a heterojunction structure 11 disposed on the substrate 10; the heterojunction structure 11 includes a source region 12a, a drain region 12b, and a gate region 12c disposed between the source region 12a and the drain region 12b, and the drain region 12b is provided with a quantum well structure 13.

The substrate 10 may include a GaN-based material. the GaN-based material may include at least one of GaN, AlGaN, InGaN, or AlInGaN, and the present embodiment is not limited thereto.

The substrate 10 may also include: at least one of Al₂O₃, sapphire, silicon carbide, or silicon, and the GaN-based material thereon.

The heterojunction structure 11 may include, from the bottom to top, a channel layer 11a and a potential barrier layer 11b. Specifically, a) one channel layer 11a and one potential barrier layer 11b may be provided; or b) multiple channel layers 11a and multiple potential barrier layers 11b may be provided, and the multiple channel layers 11a and the multiple potential barrier layers 11b are arranged alternately; or c) one channel layer 11a and two or more potential barrier layers 11b are provided, to meet different functional requirements.

A material combination of the channel layer 11a and the potential barrier layer 11b may includes: GaN and AlN, GaN and InN, GaN and InAlGaN, GaAs and AlGaAs, GaN and InAlN, or InN and InAlN.

A nucleation layer and a buffer layer (not shown in the figures) may also be provided between the heterojunction structure 11 and the substrate 10. The material of the nucleation layer may include, for example, AlN, AlGaN, etc., and the material of the buffer layer may include at least one of AlN, GaN, AlGaN or AlInGaN. The nucleation layer can alleviate the problem of lattice mismatch and thermal mismatch between the epitaxially grown semiconductor layers, such as the channel layer 11a in the heterojunction structure 11 and the substrate 10, and the buffer layer can reduce the dislocation density and defect density of the epitaxially grown semiconductor layers and improve the crystal quality.

Referring to FIG. 1, in this embodiment, the quantum well structure 13 includes an N-type semiconductor layer 13a, a first P-type semiconductor layer 13b, and a quantum well layer 13c disposed between the N-type semiconductor layer 13a and the first P-type semiconductor layer 13b.

The N-type semiconductor layer 13a is used to provide electrons and the first P-type semiconductor layer 13b is used to provide holes to achieve recombination luminescence of the electrons and the holes in the quantum well layer 13c. The N-type semiconductor layer 13a and/or the first P-type semiconductor layer 13b may include a GaN-based material. The GaN-based material may include at least one of GaN, AlGaN, InGaN or AlInGaN. An N-type doping element in the N-type semiconductor layer 13a may be Mg, and a P-type doping element in the first P-type semiconductor layer 13b may be Si.

In the embodiment shown in FIG. 1, the N-type semiconductor layer 13a is close to the heterojunction structure 11 and the first P-type semiconductor layer 13b is away from the heterojunction structure 11, or in other embodiments, the first P-type semiconductor layer 13b may be close to the heterojunction structure 11 and the N-type semiconductor layer 13a is away from the heterojunction structure 11.

The quantum well layer 13c may be a single quantum well layer or a multiple quantum well layer.

In the semiconductor structure 1, the drain region 12b of the heterojunction structure 11 is provided with the quantum well structure 13, and the quantum well structure 13 is used to generate photons by recombination luminescence, and the photons can accelerate the release process of electrons captured by defects, to reduce the current collapse effect as well as the dynamic on-resistance. In addition, the photons can be radiated not only on the surface region of the potential barrier layer 11b but also into the interior of the heterojunction structure 11. In other words, not only the release process of electrons in the surface region of the potential barrier layer can be accelerated, but also the release process of electrons inside the heterojunction structure can be accelerated, such that the current collapse effect and the dynamic on-resistance are reduced.

The semiconductor structure 1 can be produced and sold as a semi-finished product of a semiconductor device.

FIG. 2 is a cross-sectional view illustrating a semiconductor structure according to a second embodiment of the present disclosure.

Referring to FIG. 2, the semiconductor structure 2 of the second embodiment is substantially the same as the semiconductor structure 1 of the first embodiment, the difference is only in that the potential barrier layer 11b is an N-type semiconductor layer to serve as an N-type semiconductor layer 13a in the quantum well structure 13. In other words, there is no need to additionally configure the N-type semiconductor layer 13a in the quantum well structure 13.

In the second embodiment, the channel layer 11a may be an intrinsic semiconductor layer.

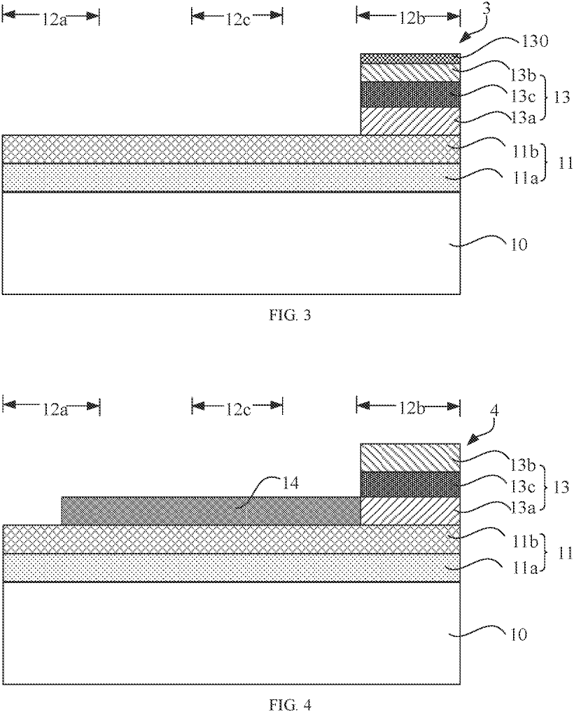

FIG. 3 is a cross-sectional view illustrating a semiconductor structure according to a third embodiment of the present disclosure.

Referring to FIG. 3, the semiconductor structure 3 of the third embodiment is substantially the same as the semiconductor structures 1 and 2 of the first and second embodiments, the difference is only in that the first P-type semiconductor layer 13b includes a hole passivation layer 130 away from the quantum well layer 13c.

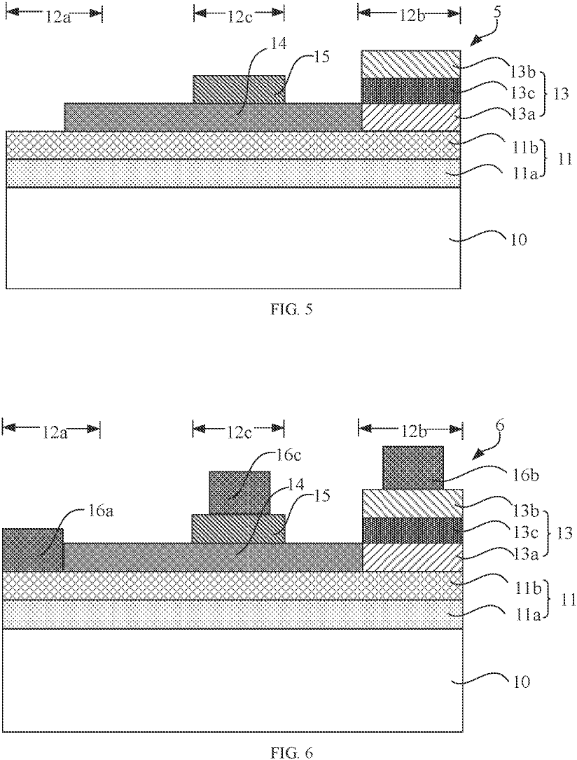

The hole passivation layer 130 prevents the electrons in the gate electrode 16c (shown with reference to FIG. 6) from recombining with the holes in the first P-type semiconductor layer 13b. In other words, the hole passivation layer 130 can create a high resistance blocking state between the gate electrode 16c and the first drain electrode 16b (shown with reference to FIG. 6).

The hole passivation layer 130 can be achieved by injecting H ions into the first P-type semiconductor layer 13b. The H ions can passivate the P-type doping ion Mg of the first P-type semiconductor layer 13b so that Mg does not generate holes.

FIG. 4 is a cross-sectional view illustrating a semiconductor structure according to a fourth embodiment of the present disclosure.

Referring to FIG. 4, the semiconductor structure 4 of the fourth embodiment is substantially the same as the semiconductor structures 1, 2, and 3 of the first, second and third embodiments, the difference is only in that the gate region 12c is provided with a dielectric layer 14.

The material of the dielectric layer 14 may include silicon dioxide or silicon nitride, etc. The dielectric layer 14 can change the degree of polarization of the gate region 12c in the heterojunction structure 11, so that the semiconductor structure 4 is in a normally closed state.

FIG. 5 is a cross-sectional view illustrating a semiconductor structure according to a fifth embodiment of the present disclosure.

Referring to FIG. 5, the semiconductor structure 5 of the fifth embodiment is substantially the same as the semiconductor structure 4 of the fourth embodiment, the difference is only in that the dielectric layer 14 of the gate region 12c is provided with a second P-type semiconductor layer 15.

The material of the second P-type semiconductor layer 15 may include at least one of GaN, AlGaN, InGaN or AlInGaN, and the P-type doping element may be Mg.

The second P-type semiconductor layer 15 may consume two-dimensional electron gas in the gate region 12c in the heterojunction structure 11, such that the semiconductor structure 5 is in a normally closed state.

The second P-type semiconductor layer 15 in the fifth embodiment can be combined with the semiconductor structures 1, 2, and 3 of the first, second and third embodiments, i.e., the gate region 12c is provided with the second P-type semiconductor layer 15.

FIG. 6 is a cross-sectional view illustrating a semiconductor structure according to a sixth embodiment of the present disclosure.

Referring to FIG. 6, the semiconductor structure 6 of the sixth embodiment is substantially the same as the semiconductor structures 1, 2, 3, 4, and 5 of the first to fifth embodiments. The difference is only in that: the source region 12a is provided with a source electrode 16a, the quantum well structure 13 is a first drain electrode 16b, and the gate region 12c is provided with a gate electrode 16c; the source electrode 16a is in ohmic contact with the heterojunction structure 11, and the first drain electrode 16b is in ohmic contact with the quantum well structure 13, and the gate electrode 16c is in Schottky contact with the heterojunction structure 11.

The material of at least one of the source electrode 16a, the first drain electrode 16b or the gate electrode 16c may include a metal, such as Ti/Al/Ni/Au, Ni/Au, and other existing conductive materials.

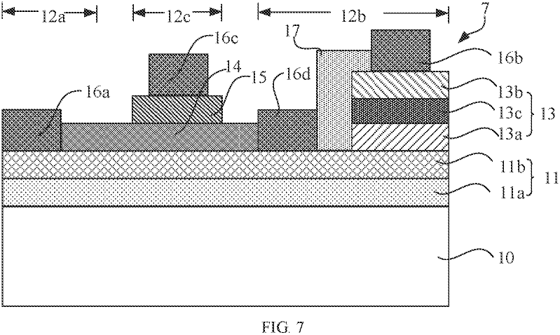

FIG. 7 is a cross-sectional view illustrating a semiconductor structure according to a seventh embodiment of the present disclosure.

Referring to FIG. 7, the semiconductor structure 7 of the seventh embodiment is substantially the same as the semiconductor structures 1, 2, 3, 4, 5, 6 of the first to sixth embodiments, the difference is only in that the drain region 12b is provided with a second drain electrode 16d, and the second drain electrode 16d is in ohmic contact with the heterojunction structure 11.

The first drain electrode 16b and the second drain electrode 16d may be connected in parallel. The first drain electrode 16b and the second drain electrode 16d can perform different functions when the same potential or different potentials are applied, depending on the specific design of the semiconductor structure 7.

In the semiconductor structure 7 shown in FIG. 7, the second drain electrode 16d is disposed between the gate electrode 16c and the first drain electrode 16b. In some embodiments, the first drain electrode 16b may also be disposed between the gate electrode 16c and the second drain electrode 16d.

In the semiconductor structure 7 shown in FIG. 7, the first drain electrode 16b and the quantum well structure 13 are electrically insulated from the second drain electrode 16d by an insulating layer 17. The insulating layer 17 may include a material such as silicon dioxide, silicon nitride, etc. In some embodiments, the insulating layer 17 may also be omitted.

Although the present disclosure is disclosed as above, the present disclosure is not limited thereto. Any person skilled in the art may make various changes and modifications without departing from the spirit and scope of the present disclosure, and therefore the scope of the present disclosure shall be as defined by the claims.

1. A semiconductor structure comprising:
a substrate and a heterojunction structure disposed on the substrate, wherein the heterojunction structure comprises a source region, a drain region, and a gate region disposed between the source region and the drain region, and the drain region is provided with a quantum well structure.

2. The semiconductor structure of claim 1, wherein the quantum well structure comprises an N-type semiconductor layer, a first P-type semiconductor layer, and a quantum well layer disposed between the N-type semiconductor layer and the first P-type semiconductor layer.

3. The semiconductor structure of claim 2, wherein the first P-type semiconductor layer comprises a hole passivation layer away from the quantum well layer.

4. The semiconductor structure of claim 1, wherein the heterojunction structure comprises, from bottom to top, a channel layer and a potential barrier layer.

5. The semiconductor structure of claim 4, wherein the potential barrier layer is served as an N-type semiconductor layer in the quantum well structure.

6. The semiconductor structure of claim 4, wherein a material combination of the channel layer and the potential barrier layer comprises: GaN and AlN, GaN and InN, GaN and InAlGaN, GaAs and AlGaAs, GaN and InAlN, or InN and InAlN.

7. The semiconductor structure of claim 1, wherein the gate region is provided with at least one of a dielectric layer or a second P-type semiconductor layer.

8. The semiconductor structure of claim 2, wherein the quantum well layer is a single quantum well layer or a multiple quantum well layer.

9. The semiconductor structure of claim 2, wherein a material of the first P-type semiconductor layer comprises at least one of GaN, AlGaN, InGaN, or AlInGaN.

10. The semiconductor structure of claim 1, wherein the source region is provided with a source electrode, the quantum well structure is provided with a first drain electrode, and the gate region is provided with a gate electrode; the source electrode is in ohmic contact with the heterojunction structure, and the first drain electrode is in ohmic contact with the quantum well structure, and the gate electrode is in Schottky contact with the heterojunction structure.

11. The semiconductor structure of claim 10, wherein the drain region is further provided with a second drain electrode, and the second drain electrode is in ohmic contact with the heterojunction structure.

12. The semiconductor structure of claim 11, wherein the first drain electrode and the quantum well structure are electrically insulated from the second drain electrode by an insulating layer.

13. The semiconductor structure of claim 1, wherein the gate region is provided with at least one of a dielectric layer or a second P-type semiconductor layer, and the P-type semiconductor layer is on the dielectric layer.

14. The semiconductor structure of claim 13, wherein a material of the dielectric layer comprises at least one of silicon dioxide or silicon nitride.

15. The semiconductor structure of claim 2, wherein a material of the N-type semiconductor layer comprises at least one of GaN, AlGaN, InGaN, or AlInGaN.

16. The semiconductor structure of claim 2, wherein the N-type semiconductor layer is close to the heterojunction structure and the first P-type semiconductor layer is away from the heterojunction structure; or, the first P-type semiconductor layer is close to the heterojunction structure and the N-type semiconductor layer is away from the heterojunction structure.

17. The semiconductor structure of claim 11, wherein the first drain electrode and the second drain electrode are connected in parallel.

18. The semiconductor structure of claim 12, wherein a material of the insulating layer comprises at least one of silicon dioxide or silicon nitride.
